(19) United States
(12) Patent Application Publication
(10) Pub. No.: US 2012/0080722 A1
(43) Pub. Date: Apr. 5, 2012

(54) METHOD FOR FORMING STRAINED SEMICONDUCTOR CHANNEL AND SEMICONDUCTOR DEVICE

(75) Inventors: Haizhou Yin, Poughkeepsie, NY (US); Zhijiong Luo, Poughkeepsie, NY (US); Huilong Zhu, Poughkeepsie, NY (US)

(73) Assignee: Institute of Microelectronics,Chinese Academy of Sciences, Chaoyang District ,Beijing (CN)

(21) Appl. No.: 13/128,931

(22) PCT Filed: Feb. 25, 2011
(86) PCT No.: PCT/CN2011/071310

§ 371 Date: May 12, 2011

(30) Foreign Application Priority Data
Sep. 30, 2010 (CN) 201010501737.3

(51) Int. Cl. H01L 27/092; H01L 21/8238

(52) U.S. Cl. 257/192; 438/230; 257/E21.633; 257/E27.062

(57) ABSTRACT

A semiconductor device includes: a semiconductor substrate; a SiGe relaxed layer on the semiconductor substrate; an NMOS transistor on the SiGe relaxed layer; and a PMOS transistor on the SiGe relaxed layer, in which the NMOS transistor includes a tensile strained epitaxial layer located on the SiGe relaxed layer or embedded in the SiGe relaxed layer; and the PMOS transistor includes a compressive strained epitaxial layer located on the SiGe relaxed layer or embedded in the SiGe relaxed layer. The loss of the strained semiconductor material can be avoided and meanwhile the stress in the channel can be better maintained.

### BACKGROUND OF THE INVENTION

1. Field of the Invention

The present invention relates to the field of semiconductor, and in particular, to semiconductor devices and manufacturing methods thereof. More specifically, the present invention relates to a method for forming strained semiconductor channel and semiconductor devices manufactured by the method.

2. Description of the Prior Art

In SiGe semiconductor devices, a tensile strained Si layer arranged on a SiGe relaxed layer is extensively used. Usually, the composition of the SiGe relaxed layer is expressed by Si₁₋ₓGeₓ, xε[0,1].

FIG. 1A shows a diagram of the atomic lattice of the tensile strained Si layer arranged on the SiGe relaxed layer. FIG. 1B shows an energy level structure of the tensile strained Si layer arranged on the SiGe relaxed layer. As shown in FIG. 1B, due to the large biaxial tensile stress in the tensile strained Si layer, the conduction band in the tensile strained Si layer is lower than the conduction band in the SiGe relaxed layer. According to this structure, a very high electron in-plane mobility can be expected in the tensile strained Si layer.

FIG. 2A and FIG. 2B show the results of theoretical studies on the impact of strain on hole mobility, see K. Sawano, etc., Applied Physics Letters (Volume 87, Page 192102, 2005). These studies have shown that compressive strain in the Ge channel on the SiGe helps to improve hole mobility.

FIGS. 3A, 3B and 3C respectively show three conventional methods for forming a strained Si channel. FIG. 3A shows a strained Si/bulk SiGe Metal Oxide Semiconductor Field-Effect Transistor (MOSFET) structure. FIG. 3B shows a SiGe-On-Insulator (SGOI) MOSFET structure. FIG. 3C shows a Strained Si Directly On Insulator (SSDOI) MOSFET structure.

However, in the conventional methods for forming the Si channel, a strained Si layer must be formed on the SiGe layer (or the buried oxide layer) before the device manufacturing process (for example, Shallow Trench Isolation (STI), gate formation, etc.). This may also lead to the following problems in the conventional methods for forming the Si channel: (1) during the device manufacturing process, the strained Si layer may be partially etched away. For example, pad oxidation process in the STI process, sacrificial oxidation process before the gate formation process, and a variety of wet chemical cleaning treatment, may lead to loss of the strained Si layer; (2) the strained Si layer may get relaxed (i.e. the stress is released) in high temperature steps. For example, the annealing process for activating source/drain dopants may cause the strain in the strained Si layer to be released.

### SUMMARY OF THE INVENTION

Considering these disadvantages of traditional technology, the present invention provides a method for forming a strained semiconductor channel, which forms the strained semiconductor channel, which comprises a channel comprising a tensile strained Si layer and a channel comprising a compressive strained Ge layer, after removing a dummy gate, thus avoiding the strained semiconductor channel exposed to high-temperature source/drain annealing. Further, the loss of strained semiconductor material can be avoided by reducing the process steps experienced by the strained semiconductor channel. Meanwhile, the stress in the channel can be better maintained. According to the method for forming the strained semiconductor channel of the present invention, the tensile strained Si layer and the compressive strained Ge layer are integrated on a SiGe substrate. The tensile strained Si layer can improve electron mobility in NMOS transistors electron mobility, while the compressive strained Ge layer can improve hole mobility in PMOS transistors, thus dual-strain (tensile strain and compressive strain) can be provided in a semiconductor device comprising NMOS transistors and PMOS transistors. In addition, the present invention also provides a semiconductor device manufactured by the method.

One aspect of the present invention provides a method for forming a strained semiconductor channel, comprising: forming a SiGe relaxed layer on a semiconductor substrate; forming a semiconductor structure comprising an NMOS transistor and a PMOS transistor on the SiGe relaxed layer, wherein each of the NMOS transistor and the PMOS transistor respectively comprises a dummy gate stack having a dielectric layer and a dummy gate; removing the dummy gate stacks to form openings; and forming a tensile strained epitaxial layer in the opening of the NMOS transistor, and forming a compressive strained epitaxial layer in the opening of the PMOS transistor.

Preferably, the tensile strained epitaxial layer is made of a material having a lattice constant less than that of the SiGe relaxed layer in a relaxed state, and the compressive strained epitaxial layer is made of a material having a lattice constant larger than that of the SiGe relaxed layer in a relaxed state.

Preferably, the tensile strained epitaxial layer and the compressive strained epitaxial layer are both made of SiGe; the atomic percentage of Ge in the tensile strained epitaxial layer is less than the atomic percentage of Ge in the SiGe relaxed layer; and the atomic percentage of Ge in the compressive strained epitaxial layer is larger than the atomic percentage of Ge in the SiGe relaxed layer.

Preferably, the tensile strained epitaxial layer is made of Si, and the compressive strained epitaxial layer is made of Ge.

Preferably, the material for forming the tensile strained epitaxial layer comprises Si:C.

Preferably, forming the tensile strained epitaxial layer and the compressive strained epitaxial layer comprises: forming a mask and performing lithography, to cover the opening at the PMOS transistor and expose the opening at the NMOS transistor; forming the tensile strained epitaxial layer by selective epitaxial growth of a tensile strained material in the opening at the NMOS transistor; forming another mask and performing lithography, to cover the opening at the NMOS transistor and expose the opening at the PMOS transistor; and forming the compressive strained epitaxial layer by selective epitaxial growth of a compressive strained material in the opening at the PMOS transistor.

Preferably, the method for forming a strained semiconductor channel further comprises the following step before the selective epitaxial growth of the tensile strained material and/or the compressive strained material: etching the SiGe relaxed layer in the opening to form a space for the epitaxial growth of the tensile strained material and/or the compressive strained material.

Preferably, an etching stop layer is formed in the step of forming the SiGe relaxed layer.

Preferably, the atomic percentage of Ge in the etching stop layer is different from that in the SiGe relaxed layer.

Another aspect of the present invention provides a semiconductor device, comprising: a semiconductor substrate; a SiGe relaxed layer on the semiconductor substrate; an NMOS transistor on the SiGe relaxed layer; and a PMOS transistor on the SiGe relaxed layer, wherein the NMOS transistor comprises a tensile strained epitaxial layer located on the SiGe relaxed layer or embedded in the SiGe relaxed layer; and the PMOS transistor comprises a compressive strained epitaxial layer located on the SiGe relaxed layer or embedded in the SiGe relaxed layer.

Preferably, each of the NMOS transistor and the PMOS transistor comprises a gate stack formed having a gate electrode and a dielectric layer formed by the replacement gate process.

Preferably, the tensile strained epitaxial layer is made of a material having a lattice constant less than that of the SiGe relaxed layer in a relaxed state, and the compressive strained epitaxial layer is made of a material having a lattice constant larger than that of the SiGe relaxed layer in a relaxed state.

Preferably, the tensile strained epitaxial layer and the compressive strained epitaxial layer are both made of SiGe; the atomic percentage of Ge in the tensile strained epitaxial layer is less than the atomic percentage of Ge in the SiGe relaxed layer; and the atomic percentage of Ge in the compressive strained epitaxial layer is larger than the atomic percentage of Ge in the SiGe relaxed layer.

Preferably, the tensile strained epitaxial layer is made of Si, and the compressive strained epitaxial layer is made of Ge.

Preferably, the material for forming the tensile strained epitaxial layer comprises Si:C.

Preferably, the SiGe relaxed layer further comprises an etching stop layer.

Preferably, the atomic percentage of Ge in the etching stop layer is different from that in the SiGe relaxed layer.

According to the present invention, it is not necessary to form the tensile strained Si layer and the compressive strained Ge layer on the SiGe layer (or buried oxide layer) before device manufacturing process. On the contrary, using the dummy gate process, the strained semiconductor layer is formed after removal of the dummy gate, thus avoiding the strained semiconductor channel exposed to high-temperature source/drain annealing. Further, the loss of strained semiconductor material can be avoided by reducing the process steps experienced by the strained semiconductor channel. Meanwhile, the stress in the channel can be better maintained.

### BRIEF DESCRIPTION OF THE DRAWINGS

Preferred embodiments of the present invention will be described with reference to the drawings, whereby the above and other objects, features and advantages will become apparent, wherein:

FIG. 1A shows a diagram of an atom lattice of a tensile strained Si layer structure arranged on a SiGe relaxed layer;

FIG. 1B shows an energy level structure of the tensile strained Si layer arranged on the SiGe relaxed layer;

FIGS. 2A and 2B show the results of theoretical studies on the impact of strain on hole mobility;

FIGS. 3A, 3B, and 3C show three conventional methods for forming a strained Si channel, respectively;

FIGS. 4-19 show respective steps of a method for forming a semiconductor device according to a first embodiment of the present invention, wherein FIG. 19 shows a semiconductor device manufactured by the method for manufacturing a semiconductor device according to the first embodiment of the present invention;

FIGS. 4-9 and 20-28 show respective steps of a method for forming a semiconductor device according to a second embodiment of the present invention, wherein FIG. 28 shows a semiconductor device manufactured by the method for manufacturing a semiconductor device according to the second embodiment of the present invention.

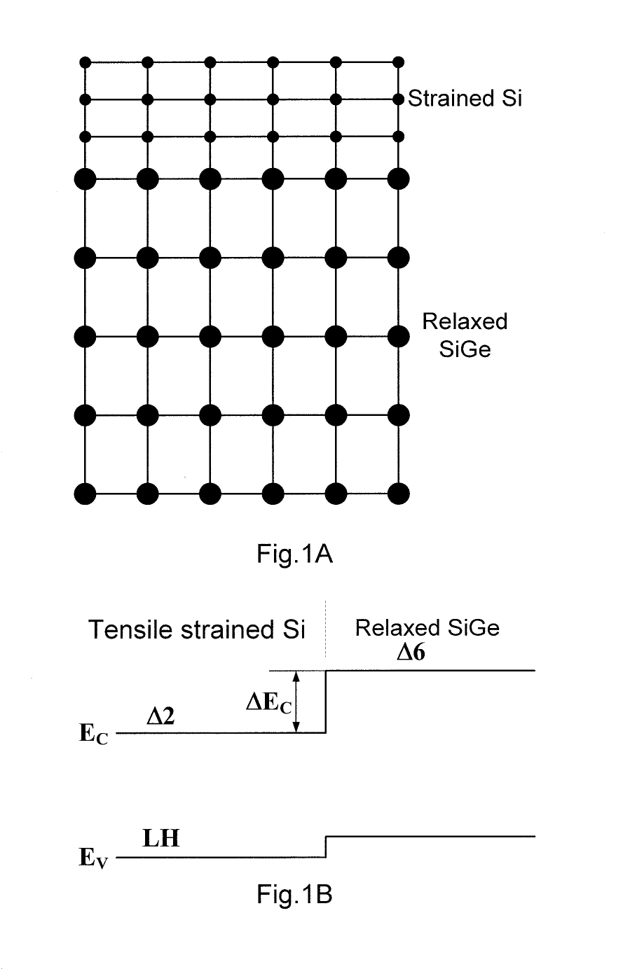

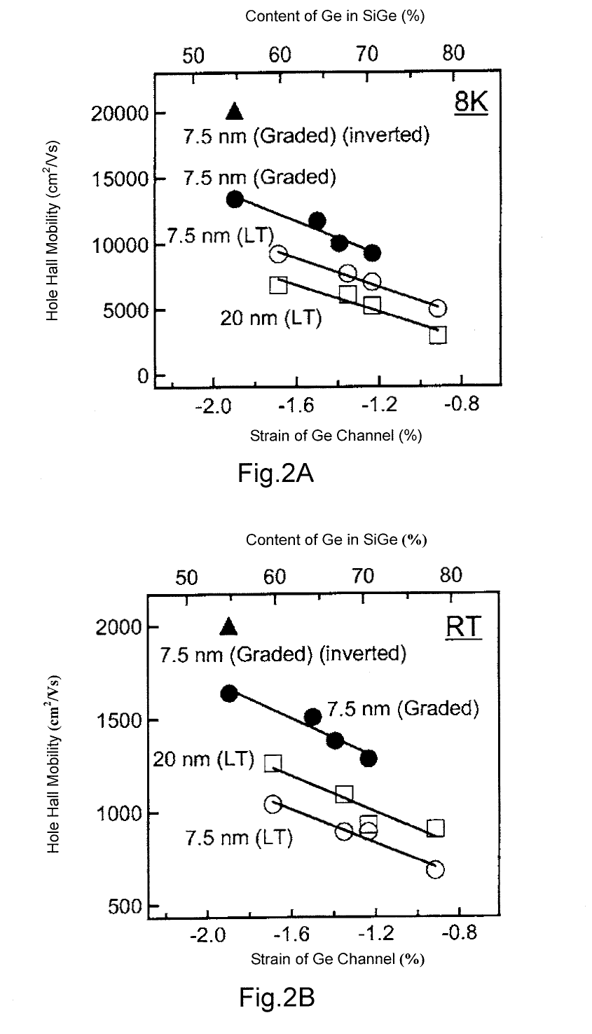

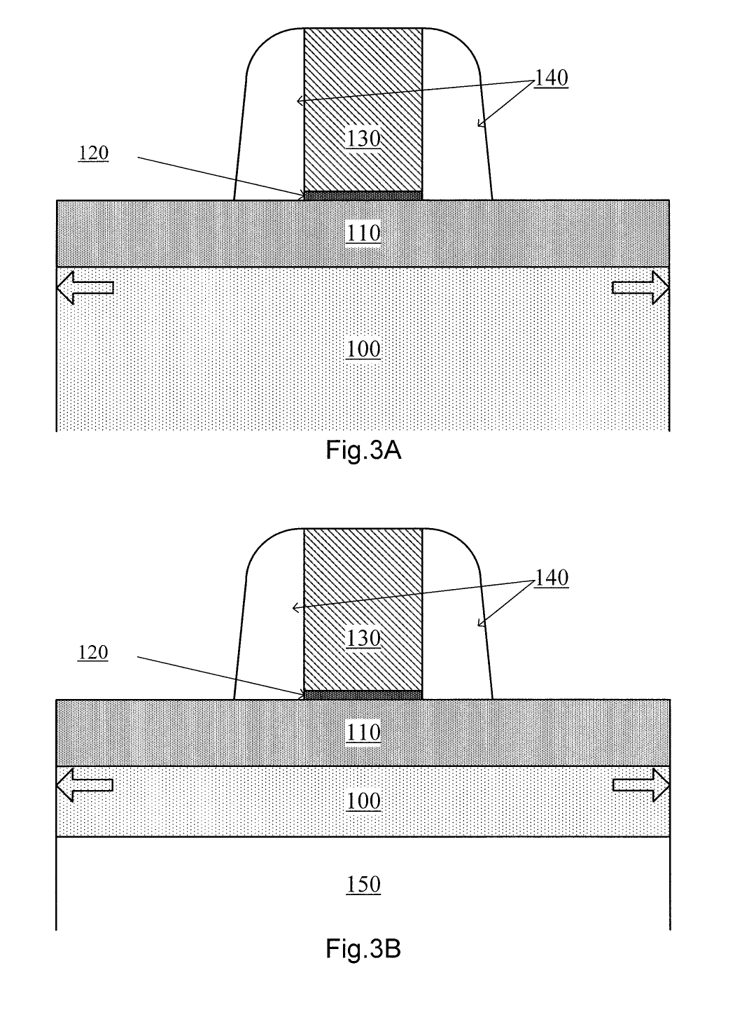

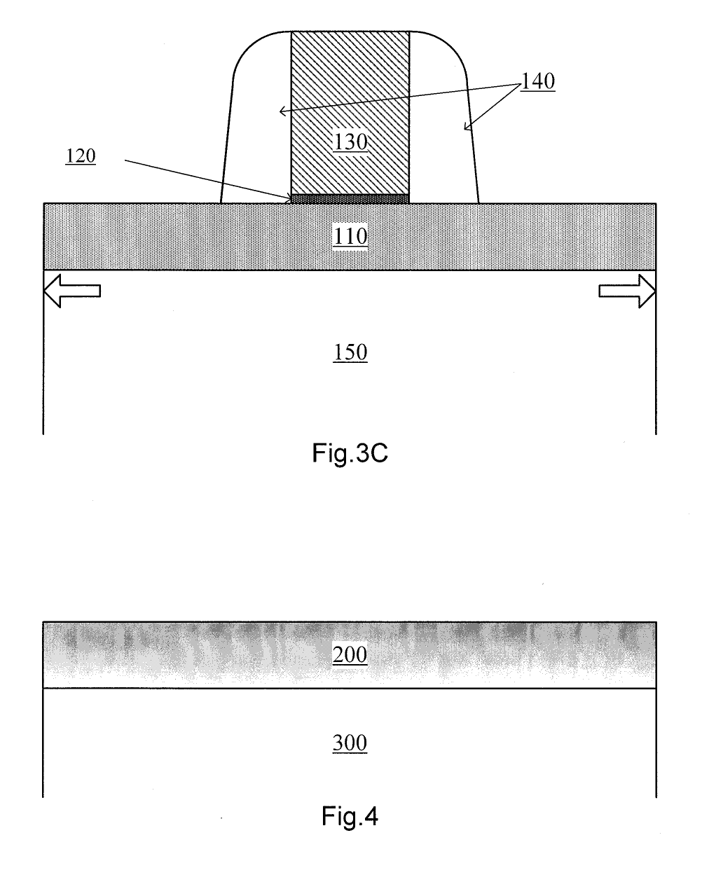

It should be noted that the drawings are not drawn to scale and are only for illustration purpose. Therefore, the drawings should not be construed as any limit or constraint to the scope of the present invention. In the drawings, similar parts are referred to by similar reference numbers.

### DETAILED DESCRIPTION OF THE PREFERRED EMBODIMENTS

The preferred embodiments of the present invention will be described in detail with reference to the drawings, wherein details and functions that are not crucial to the present invention are omitted, in order not to obscure the understanding to the present invention.

### First Embodiment

First, a semiconductor device manufactured by a process according to a first embodiment of the present invention is described in detail with reference to FIG. 19. FIG. 19 shows a diagram of a semiconductor device manufactured by the method for manufacturing a semiconductor device according to the first embodiment of the present invention.

As shown in FIG. 19, the semiconductor device manufactured by the process according to the first embodiment of the present comprises: a substrate 300 (Si wafer, SOI, etc.), a SiGe relaxed layer 200 (the atomic percentage of Ge changes from 20% to 100% in a bottom-to-top direction in FIG. 19), an interlayer dielectric layer 250 (with a thickness of 15-50 nm), an NMOS transistor and a PMOS transistor, wherein the SiGe relaxed layer 200 is formed on the substrate 300, and the interlayer dielectric layer 250 is deposited on the SiGe relaxed layer 200.

The NMOS transistor comprises: a Si epitaxial layer 260n (with a thickness of 5-10 nm), a high-K dielectric layer 320₁ (with a thickness of 1-3 nm), a metal gate 330₁ and Si₃N₄ spacers 240n (with a width of 10-40 nm), wherein an NMOS transistor gate structure having the Si₃N₄ spacers 240n, the Si epitaxial layer 260n, the high-K dielectric layer 320₁ and the metal gate 330₁ is formed on the SiGe relaxed layer 200; the interlayer dielectric layer 250 surrounds an outer periphery of the Si₃N₄ spacers 240n of the NMOS transistor gate structure; the Si epitaxial layer 260n is formed on the SiGe relaxed layer 200 and embedded in the SiGe relaxed layer 200; the high-K dielectric layer 320₁ is deposited on the whole surface of the Si epitaxial layer 260n, and formed as a hollow cylinder having a bottom; the metal gate 330₁ is filled inside the hollow cylinder formed by the high-K dielectric layer 320₁; and the Si₃N₄ spacers 240n are formed on the SiGe relaxed layer 200 and surrounds an outer periphery of the high-K dielectric layer 320₁.

The PMOS transistor comprises: a Ge epitaxial layer 260p (with a thickness of 5-10 nm), a high-K dielectric layer 320₂ (with a thickness of 1-3 nm), a metal gate 330₂ and Si₃N₄ spacers 240p (with a width of 10-40 nm), wherein an PMOS transistor gate structure having the Si₃N₄ spacers 240p, the Ge epitaxial layer 260p, the high-K dielectric layer 320₂ and the metal gate 330₂ is formed on the SiGe relaxed layer 200; the interlayer dielectric layer 250 surrounds an outer periphery of the Si₃N₄ spacers 240p of the PMOS transistor gate structure; the Ge epitaxial layer 260p is formed on the SiGe relaxed layer 200 and embedded in the SiGe relaxed layer 200; the high-K dielectric layer 320₂ is deposited on the whole surface of the Ge epitaxial layer 260p, and formed as a hollow cylinder having a bottom; the metal gate 330₂ is filled inside the hollow cylinder formed by the high-K dielectric layer 320₂; and the Si₃N₄ spacers 240p are formed on the SiGe relaxed layer 200 and surrounds an outer periphery of the high-K dielectric layer 320₂.

It should be noted that Shallow Trench Isolation (STI) structures or other conventional transistor structures (not shown) can be arranged between the NMOS transistor gate structure and the PMOS transistor gate structure.

According to the first embodiment of the present invention, it is not necessary to form the tensile strained Si layer and the compressive strained Ge layer on the SiGe relaxed layer 200 before device manufacturing process, and particularly before forming the source/drain regions. On the contrary, the Si epitaxial layer 260n and the Ge epitaxial layer 260p are formed after removing the dummy gate and forming the source/drain regions by the replacement gate process, thus avoiding the high-temperature source/drain annealing to the strained Si channel and the stained Ge channel. Further, the loss of Si epitaxial layer 260n and the Ge epitaxial layer 260p can be avoided by reducing the processing steps experienced by the strained Si channel and the stained Ge channel. Meanwhile, the stress in the channel can be better maintained.

Next, respective steps of the method for manufacturing the semiconductor device according to the first embodiment of the present invention will be described in detail with reference to FIGS. 4-19.

First, as shown in FIG. 4, a SiGe relaxed layer 200 is formed on the substrate 300 (Si wafer, SOI, etc.). In the SiGe relaxed layer 200, the atomic percentage of Ge (i.e. the percentage of the number of Ge atoms among the total number of atoms) changes gradually from e.g. 20% to 100% in the bottom-to-top direction as shown in FIG. 4. That is, the index x in Si₁₋ₓGeₓ changes gradually from 0.2 to 1. The specific value of the composition of the SiGe relaxed layer 200 is only for purpose of explanation. Those skilled in the art may select other suitable compositions (i.e. reset the variation range of the index x) according to actual requirement. The index x may vary linearly, hyperbolically, or exponentially. Optionally, as shown in FIG. 10, an etching stop layer can be formed in the SiGe relaxed layer 200 (e.g. by changing the atomic percentage of Ge), to control the depth of etching to be performed in the step shown in FIG. 10. Particularly, a stacked structure of a relaxed layer/an etching stop layer/a relaxed layer can be formed in the SiGe relaxed layer 200 according to actual requirement to control the etching depth.

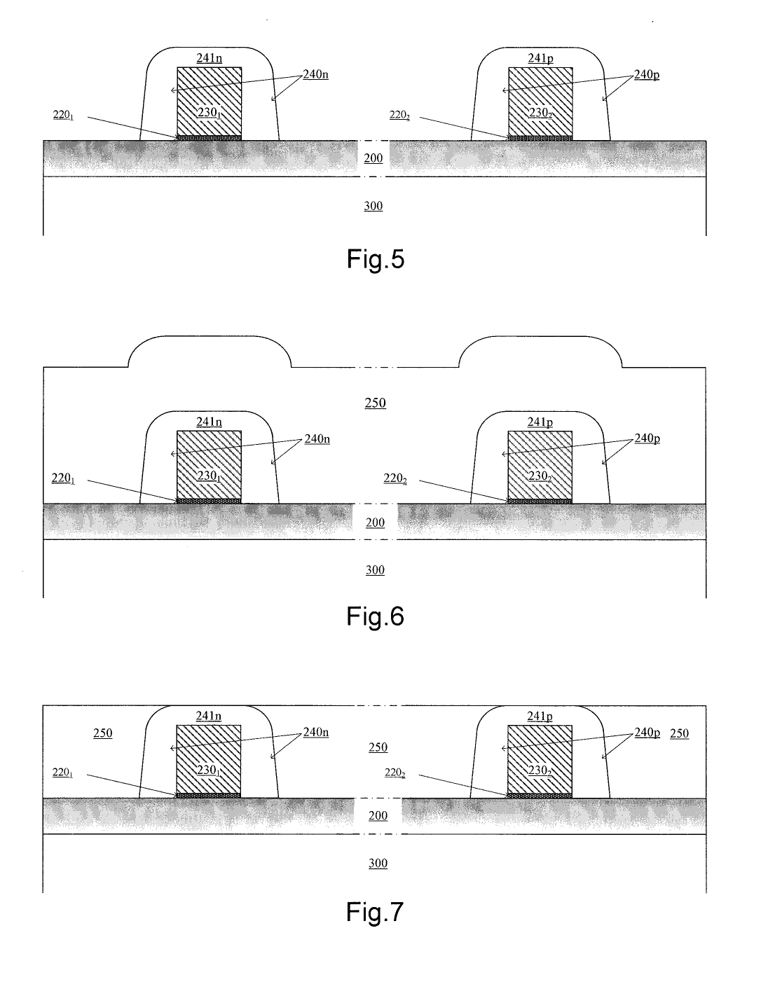

Next, as shown in FIG. 5, an NMOS transistor dummy gate structure (a dielectric layer 220₁, a dummy gate 230₁ (a polysilicon gate 230₁ as shown, or other materials well known in the art), and Si₃N₄ spacers 240n and a Si₃N₄ layer 241n surrounding and the covering dielectric layer 220₁ and the polysilicon gate 230₁) and a PMOS transistor dummy gate structure (a dielectric layer 220₂, a dummy gate 230₂ (a polysilicon gate 230₂ as shown, or other materials well known in the art), Si₃N₄ spacers 240p and a Si₃N₄ layer 241p surrounding and covering the dielectric layer 220₂ and the polysilicon gate 230₂) are formed on the SiGe relaxed layer 200. As an example of the present invention, the thickness of the dielectric layers 220₁ and 220₂ is 1-3 nm, the thickness of the polysilicon gates 230₁ and 230₂ is 20-70 nm, the width of the Si₃N₄ spacers 240n and 240p in a horizontal direction as shown is 10-40 nm, and the thickness of the Si₃N₄ layers 241n and 241p is 15-40 nm. This step is also a part of the conventional process, which forms the polysilicon gates 230₁ and 230₂ as dummy gates being replaced by the metal gates. Optionally, source/drain regions (not shown) are formed by the conventional process (e.g. ion implantation and high-temperature annealing) in the semiconductor intermediate structure having the NMOS transistor dummy gate structure and the PMOS transistor dummy gate structure. In addition, a Shallow Trench Isolation STI may be formed between the NMOS transistor dummy gate structure and the PMOS transistor dummy gate structure.

Then, as shown in FIG. 6, an interlayer dielectric layer 250 is deposited on the SiGe relaxed layer 200, on which the NMOS transistor dummy gate structure and the PMOS transistor dummy gate structure are formed. For example, the interlayer dielectric layer 250 may be made of materials such as undoped silicon oxide (SiO₂), various doped silicon oxide (e.g. borosilicate glass, Borophosphosilicate glass, etc.), and silicon nitride (Si₃N₄).

Next, as shown in FIG. 7, the interlayer dielectric layer 250 is processed by Chemical Mechanical Planarization (CMP) to expose the Si₃N₄ layers 241n and 241p of the dummy gate structures.

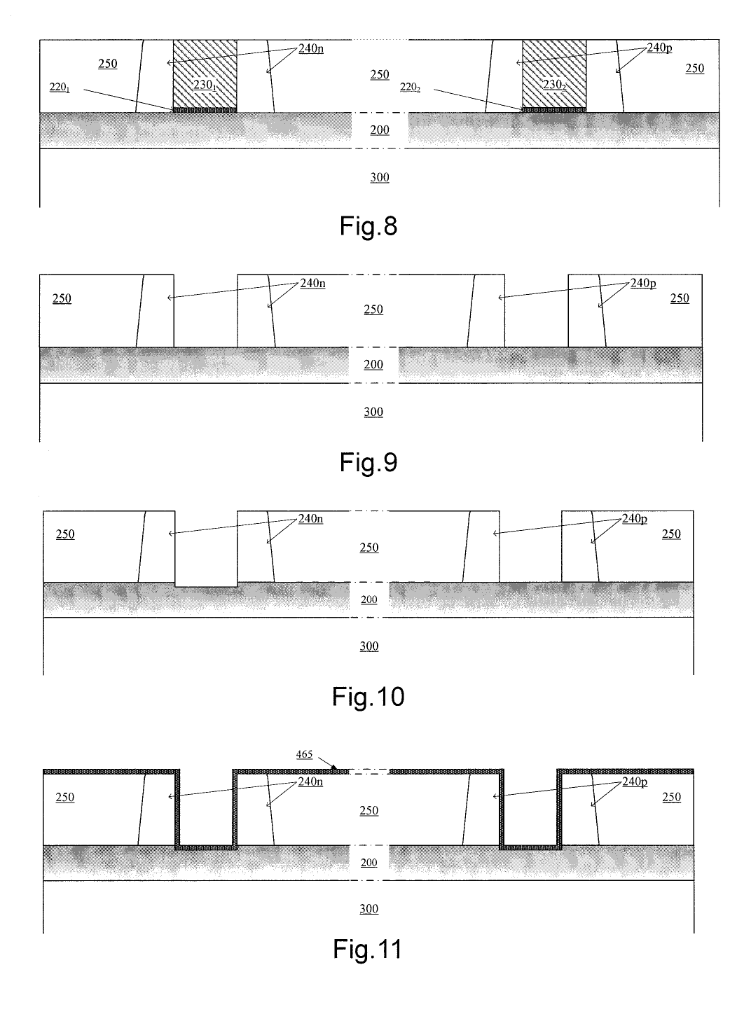

Next, as shown in FIG. 8, a further CMP process or a Reactive Ion Etching (RIE) on Si₃N₄ is performed to remove the Si₃N₄ layer 241n and 241p, so as to expose the polysilicon gates 230₁ and 230₂ of the NMOS transistor dummy gate structure and the PMOS transistor dummy gate structure.

Then, as shown in FIG. 9, the polysilicon gates 230₁ and 230₂ are removed by wet etching or dry etching.

Next, as shown in FIG. 10, the SiGe relaxed layer 200 is etched by wet etching or dry etching to form a space for Si epitaxial growth and Ge epitaxial growth, wherein the etching depth is 5-10 nm. Optionally, as previously described with reference to FIG. 4, an etching stop layer can be formed in the SiGe relaxed layer 200 by e.g. changing the atomic percentage of Ge, to control the etching depth.

Next, as shown in FIG. 11, an epitaxial stop layer 465 is deposited on the whole surface of the structure shown in FIG. 10. The epitaxial stop layer may comprise e.g. a SiO₂ or Si₃N₄ film. The SiO₂ is a non-limiting example.

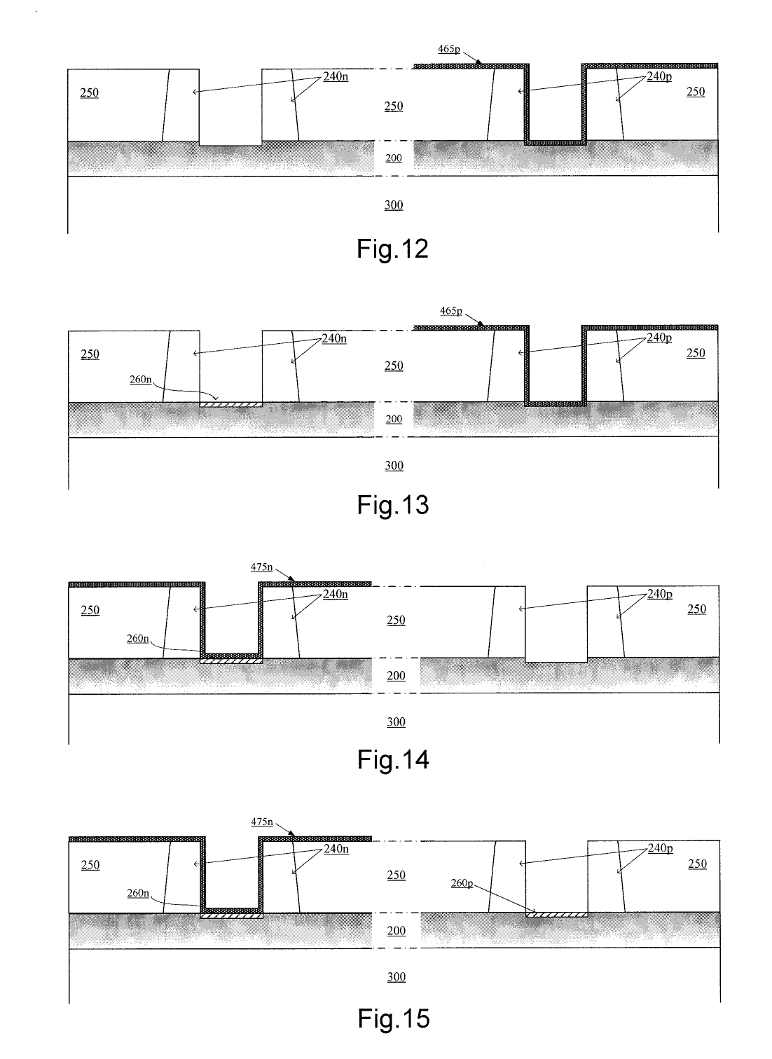

Then, as shown in FIG. 12, the SiO₂ film 465 is processed by photolithography using a mask, to remove the SiO₂ film 465 on the NMOS transistor while keep the SiO₂ film 465 on the PMOS transistor, which is referred to as 465p.

Next, as shown in FIG. 13, in an etched opening of the NMOS transistor, a Si epitaxial layer 260n embedded in the SiGe relaxed layer 200 is formed by selective epitaxial growth of Si. The top surface of the Si epitaxial layer 260n may (as shown in FIG. 13) or may not (not shown) be flush with the top surface of the SiGe relaxed layer 200.

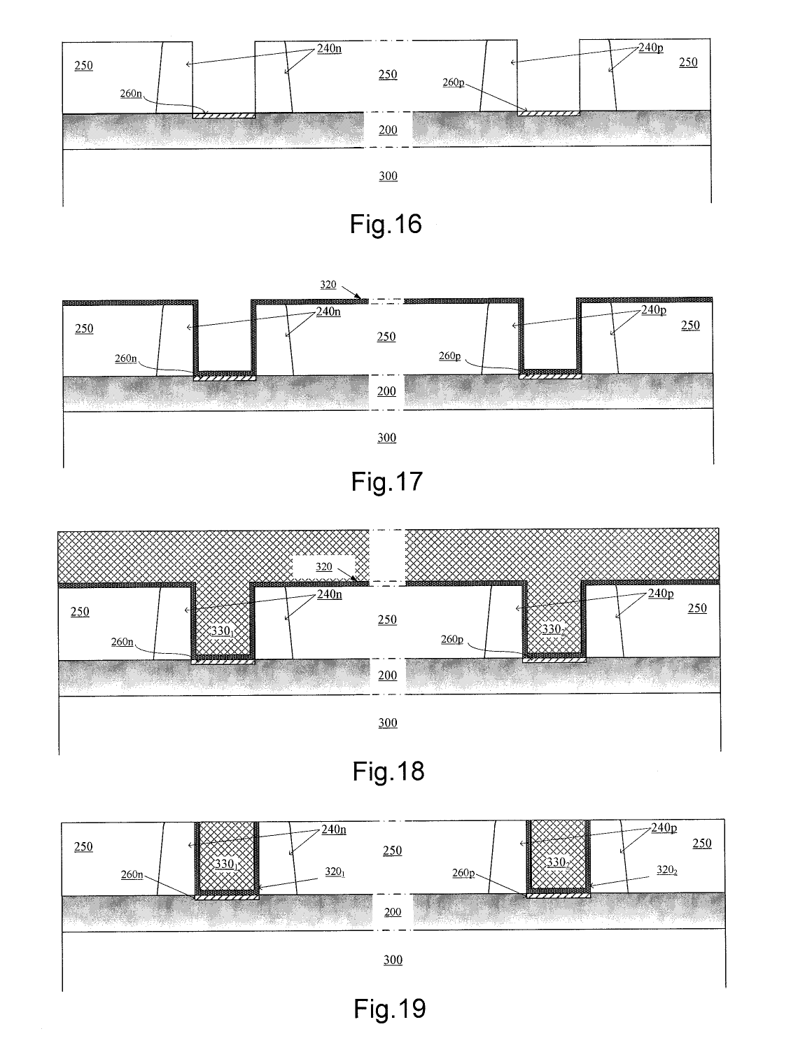

Next, as shown in FIG. 16, the SiO₂ film 475n covering the NMOS transistor is removed.

Then, as shown in FIG. 17, a high-K dielectric layer 320 having a thickness in the range of 1-3 nm is deposited on the surface of the structure shown in FIG. 16.

Then, as shown in FIG. 18, a metal layer is deposited on the surface of the high-K dielectric layer 320 for forming metal gates 330₁ and 330₂. According to the present invention, the metal layer may comprise a plurality of conductive layers. For example, a TiN layer is first deposited and then a TiAl layer is deposited.

Finally, as shown in FIG. 19, the formed metal layer and the high-K dielectric layer 320 are planarized by e.g. the CMP process to remove portions of the high-K dielectric layer 320 and the metal layer covering the interlayer dielectric layer 250 and the top surfaces of the Si₃N₄ spacers 240n and 240p, to form high-K dielectric layers 320₁ and 320₂ and metal gates 330₁ and 330₂. After this step, the polysilicon gates 230₁ and 230₂ as dummy gates have been completely replaced by the metal gates 330₁ and 330₂.

Then, further semiconductor manufacturing processes can be performed by conventional methods, for example, to form source/drain region silicide.

In alternative embodiments, the above steps can be performed in varied orders. For example, the selective epitaxial growth of Ge in the PMOS transistor can precede the selective epitaxial growth of Si in the NMOS transistor.

According to the first embodiment of the present invention, it is not necessary to form the tensile strained Si layer and the compressive strained Ge layer on the SiGe relaxed layer 200 before device manufacturing process, and particularly before forming the source/drain regions. On the contrary, the Si epitaxial layer 260n and the Ge epitaxial layer 260p are formed after removing the dummy gates and forming the source/drain regions by the replacement gate process, thus avoiding the high-temperature source/drain annealing to the strained Si channel and the stained Ge channel. Further, the loss of Si epitaxial layer 260n and the Ge epitaxial layer 260p can be avoided by reducing the processing steps experienced by the strained Si channel and the stained Ge channel. Meanwhile, the stress in the channel can be better maintained.

### Second Embodiment

First, a semiconductor device manufactured by a process according to a second embodiment of the present invention is described in detail with reference to FIG. 28. FIG. 28 shows a diagram of a semiconductor device manufactured by the method for manufacturing a semiconductor device according to the second embodiment of the present invention.

As shown in FIG. 28, the semiconductor device manufactured by the process according to the second embodiment of the present comprises: a substrate 300 (Si wafer, SOI, etc.), a SiGe relaxed layer 200 (the atomic percentage of Ge changes from 20% to 100% in a bottom-to-top direction as shown in FIG. 28), an interlayer dielectric layer 250 (with a thickness of 15-50 nm), an NMOS transistor and a PMOS transistor, wherein the SiGe relaxed layer 200 is formed on the substrate 300, and the interlayer dielectric layer 250 is deposited on the SiGe relaxed layer 200.

The NMOS transistor comprises: a Si epitaxial layer 260n (with a thickness of 5-10 nm), a high-K dielectric layer 320₁ (with a thickness of 1-3 nm), a metal gate 330₁ and Si₃N₄ spacers 240n (with a width of 10-40 nm), wherein an NMOS transistor gate structure having the Si₃N₄ spacers 240n, the Si epitaxial layer 260n, the high-K dielectric layer 320₁ and the metal gate 330₁ is formed on the SiGe relaxed layer 200; the interlayer dielectric layer 250 surrounds an outer periphery of the Si₃N₄ spacers 240n of the NMOS transistor gate structure; the Si epitaxial layer 260n is formed on a top surface of the SiGe relaxed layer 200; the high-K dielectric layer 320₁ is deposited on the whole surface of the Si epitaxial layer 260n, and formed as a hollow cylinder having a bottom; the metal gate 330₁ is filled inside the hollow cylinder formed by the high-K dielectric layer 320₁; and the Si₃N₄ spacers 240n are formed on the SiGe relaxed layer 200 and surrounds an outer periphery of the high-K dielectric layer 320₁.

The PMOS transistor comprises: a Ge epitaxial layer 260p (with a thickness of 5-10 nm), a high-K dielectric layer 320₂ (with a thickness of 1-3 nm), a metal gate 330₂ and Si₃N₄ spacers 240p (with a width of 10-40 nm), wherein an PMOS transistor gate structure having the Si₃N₄ spacers 240p, the Ge epitaxial layer 260p, the high-K dielectric layer 320₂ and the metal gate 330₂ is formed on the SiGe relaxed layer 200; the interlayer dielectric layer 250 surrounds an outer periphery of the Si₃N₄ spacers 240p of the PMOS transistor gate structure; the Ge epitaxial layer 260p is formed on a top surface of the SiGe relaxed layer 200; the high-K dielectric layer 320₂ is deposited on the whole surface of the Ge epitaxial layer 260p, and formed as a hollow cylinder having a bottom; the metal gate 330₂ is filled inside the hollow cylinder formed by the high-K dielectric layer 320₂; and the Si₃N₄ spacers 240p are formed on the SiGe relaxed layer 200 and surrounds an outer periphery of the high-K dielectric layer 320₂.

It should be noted that a Shallow Trench Isolation (STI) or other conventional transistor structures (not shown) can be arranged between the NMOS transistor gate structure and the PMOS transistor gate structure.

According to the second embodiment of the present invention, it is not necessary to form the tensile strained Si layer and the compressive strained Ge layer on the SiGe relaxed layer 200 before device manufacturing process, and particularly before forming the source/drain regions. On the contrary, the Si epitaxial layer 260n and the Ge epitaxial layer 260p are formed after removing the dummy gate and forming the source/drain regions by the replacement gate process, thus avoiding the high-temperature source/drain annealing to the strained Si channel and the stained Ge channel. Further, the loss of Si epitaxial layer 260n and the Ge epitaxial layer 260p can be avoided by reducing the processing steps experienced by the strained Si channel and the stained Ge channel. Meanwhile, the stress in the channel can be better maintained.

Next, respective steps of the method for manufacturing the semiconductor device according to the second embodiment of the present invention will be described in detail with reference to FIGS. 4-9 and 20-28.

The steps as shown in FIG. 4-9 are the same as those in the first embodiment of the present invention, and thus a detailed description thereof is omitted for simplification. The detailed description in the first embodiment applies to the second embodiment.

As shown in FIG. 9, the polysilicon gates 230₁ and 230₂ have been removed by wet etching or dry etching.

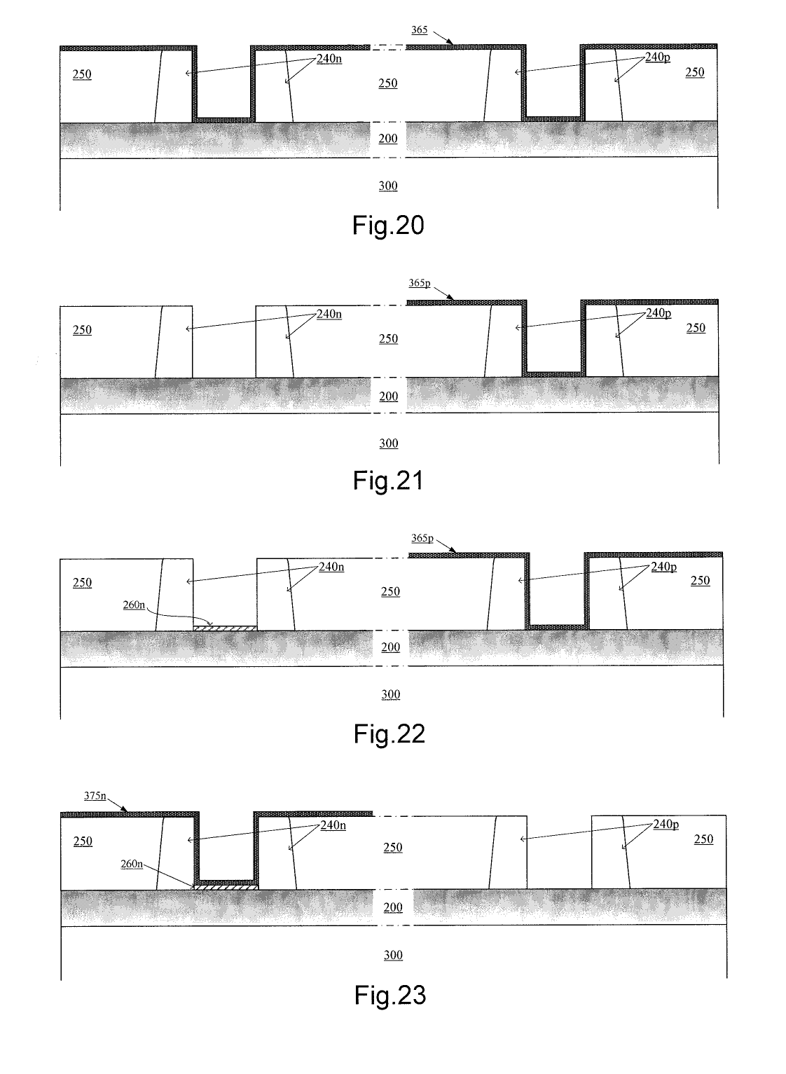

Next, as shown in FIG. 20, an epitaxial stop layer 365 is deposited on the whole surface of the structure shown in FIG. 9. The epitaxial stop layer may comprise, e.g., a SiO₂ or Si₃N₄ film. The SiO₂ is a non-limiting example.

Then, as shown in FIG. 21, the SiO₂ film 365 is processed by photolithography using a mask, to remove the SiO₂ film 365 on the NMOS transistor while keep the SiO₂ film 365 on the PMOS transistor, which is referred to as 365p.

Then, as shown in FIG. 22, a Si epitaxial layer 260n having a thickness of 5-10 nm is formed on a top surface of the SiGe relaxed layer 200 by selective epitaxial growth of Si directly on the SiGe relaxed layer 200 in an opening surrounded by the Si₃N₄ spacers 240n.

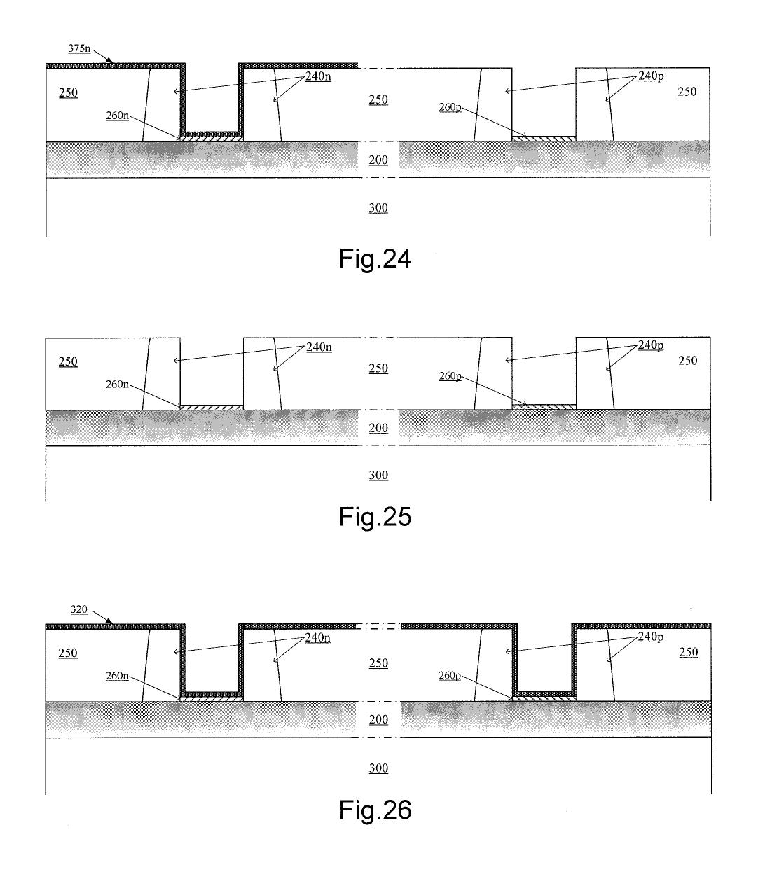

Next, as shown in FIG. 23, a SiO₂ film 375 is formed to cover the NMOS transistor, and the SiO₂ film 365p on the PMOS transistor side is removed. Then, as shown in FIG. 24, a Ge epitaxial layer 260p having a thickness of 5-10 nm is formed on a top surface of the SiGe relaxed layer 200 by selective epitaxial growth of Ge directly on the SiGe relaxed layer 200 in an opening surrounded by the Si₃N₄ spacers 240p.

Next, as shown in FIG. 25, the SiO₂ film 375n covering the NMOS transistor is removed.

Then, as shown in FIG. 26, a high-K dielectric layer 320 having a thickness of 1-3 nm is deposited on the surface of the structure shown in FIG. 25.

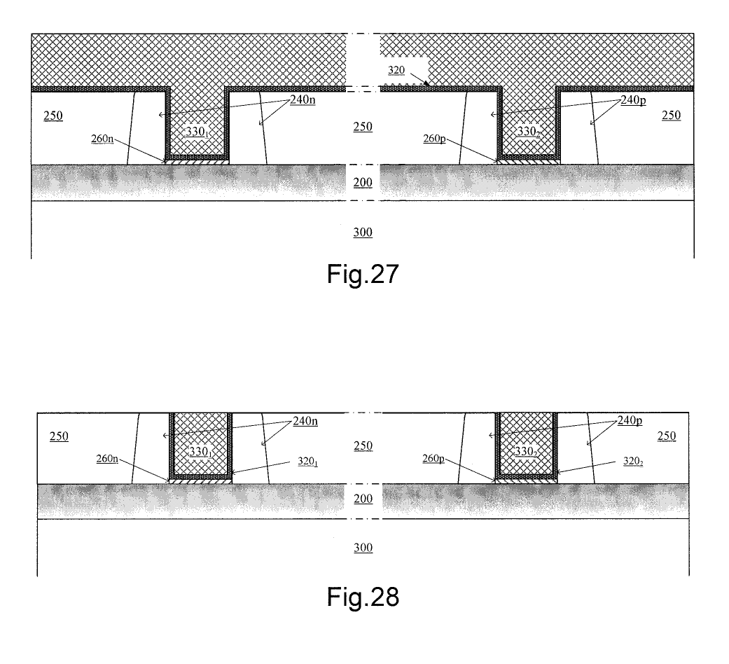

Then, as shown in FIG. 27, a metal layer is deposited on the surface of the high-K dielectric layer 320 for forming metal gates 330₁ and 330₂. According to the present invention, the metal layer may comprise a plurality of conductive layers. For example, a TiN layer is first deposited and then a TiAl layer is deposited.

Finally, as shown in FIG. 28, the formed metal layer and the high-K dielectric layer 320 are planarized by e.g. the CMP process to remove the high-K dielectric layer 320 and the metal layer covering the interlayer dielectric layer 250 and the top surfaces of the Si₃N₄ spacers 240n and 240p, so as to form high-K dielectric layers 320₁ and 320₂ and metal gates 330₁ and 330₂. After this step, the polysilicon gates 230₁ and 230₂ as dummy gates have been completely replaced by the metal gates 330₁ and 330₂.

Then, further semiconductor manufacturing processes can be performed by conventional methods, for example, to form source/drain region silicide.

In alternative embodiments, the above steps can be performed in varied orders. For example, the selective epitaxial growth of Ge in the PMOS transistor can precede the selective epitaxial growth of Si in the NMOS transistor.

According to the second embodiment of the present invention, it is not necessary to form the tensile strained Si layer and the compressive strained Ge layer on the SiGe relaxed layer 200 before device manufacturing process, and particularly before forming the source/drain regions. On the contrary, the Si epitaxial layer 260n and the Ge epitaxial layer 260p are formed after removing the dummy gates and forming the source/drain regions by the replacement gate process, thus avoiding the high-temperature source/drain annealing to the strained Si channel and the stained Ge channel. Further, the loss of Si epitaxial layer 260n and the Ge epitaxial layer 260p can be avoided by reducing the process steps experienced by the strained Si channel and the stained Ge channel. Meanwhile, the stress in the channel can be better maintained.

In addition, according to the present invention, the material forming the tensile strained epitaxial layer is not limited to the Si epitaxial layer 260n, but may be other materials, the lattice constants of which in the relaxed state are less than that of the SiGe relaxed layer 200. For example, a SiGe epitaxial layer having an atomic percentage of Ge less than that of the SiGe relaxed layer 200, or a Si:C epitaxial layer can be used.

Similarly, according to the present invention, the material forming the compressive strained epitaxial layer is not limited to the Ge epitaxial layer 260p, but may be other materials, the lattice constants of which in the relaxed state are larger than that of the SiGe relaxed layer 200. For example, a SiGe epitaxial layer having an atomic percentage of Ge larger than that of the SiGe relaxed layer 200 can be used.

The present invention has been described in connection with preferred embodiments. It should be understood that those skilled in the art can make various changes, alternations, and supplementations without departing from the spirit and scope of the present invention. Therefore, the scope of the present invention is not limited to the above specific embodiments, but is defined by the appended claims.

1. A method for forming a strained semiconductor channel, comprising:
forming a SiGe relaxed layer on a semiconductor substrate;
forming a semiconductor structure comprising an NMOS transistor and a PMOS transistor on the SiGe relaxed layer, wherein each of the NMOS transistor and the PMOS transistor comprises a dummy gate stack having a dielectric layer and a dummy gate;
removing the dummy gate stacks to form openings; and
forming a tensile strained epitaxial layer in the opening of the NMOS transistor, and forming a compressive strained epitaxial layer in the opening of the PMOS transistor.

2. The method for forming a strained semiconductor channel according to claim 1, wherein the tensile strained epitaxial layer is made of a material having a lattice constant less than that of the SiGe relaxed layer in a relaxed state, and the compressive strained epitaxial layer is made of a material having a lattice constant larger than that of the SiGe relaxed layer in a relaxed state.

3. The method for forming a strained semiconductor channel according to claim 1, wherein:
the tensile strained epitaxial layer and the compressive strained epitaxial layer are both made of SiGe;
the atomic percentage of Ge in the tensile strained epitaxial layer is less than the atomic percentage of Ge in the SiGe relaxed layer; and
the atomic percentage of Ge in the compressive strained epitaxial layer is larger than the atomic percentage of Ge in the SiGe relaxed layer.

4. The method for forming a strained semiconductor channel according to claim 1, wherein the tensile strained epitaxial layer is made of Si, and the compressive strained epitaxial layer is made of Ge.

5. The method for forming a strained semiconductor channel according to claim 1, wherein the material for forming the tensile strained epitaxial layer comprises Si:C.

6. The method for forming a strained semiconductor channel according to claim 1, wherein forming the tensile strained epitaxial layer and the compressive strained epitaxial layer comprises:
forming a mask and performing lithography, to cover the opening at the PMOS transistor and expose the opening at the NMOS transistor;
forming the tensile strained epitaxial layer by selective epitaxial growth of a tensile strained material in the opening at the NMOS transistor;
forming another mask and performing lithography, to cover the opening at the NMOS transistor and expose the opening at the PMOS transistor; and
forming the compressive strained epitaxial layer by selective epitaxial growth of a compressive strained material in the opening at the PMOS transistor.

7. The method for forming a strained semiconductor channel according to claim 6, further comprising the following step before the selective epitaxial growth of the tensile strained material and/or the compressive strained material:
etching the SiGe relaxed layer in the opening to form a space for the epitaxial growth of the tensile strained material and/or the compressive strained material.

8. The method for forming a strained semiconductor channel according to claim 1, further comprises forming an etching stop layer in the step of forming the SiGe relaxed layer.

9. The method for forming a strained semiconductor channel according to claim 8, wherein:
the atomic percentage of Ge in the etching stop layer is different from that in the SiGe relaxed layer.

10. A semiconductor device, comprising:
a semiconductor substrate;
a SiGe relaxed layer on the semiconductor substrate;
an NMOS transistor on the SiGe relaxed layer; and
a PMOS transistor on the SiGe relaxed layer,
wherein:
the NMOS transistor comprises:
a tensile strained epitaxial layer located on the SiGe relaxed layer or embedded in the SiGe relaxed layer; and
the PMOS transistor comprises:
a compressive strained epitaxial layer located on the SiGe relaxed layer or embedded in the SiGe relaxed layer.

11. The semiconductor device according to claim 10, wherein each of the NMOS transistor and the PMOS transistor comprises a gate stack having a gate electrode and a dielectric layer formed by the replacement gate process.

12. The semiconductor device according to claim 10, wherein the tensile strained epitaxial layer is made of a material having a lattice constant less than that of the SiGe relaxed layer in a relaxed state, and the compressive strained epitaxial layer is made of a material having a lattice constant larger than that of the SiGe relaxed layer in a relaxed state.

13. The semiconductor device according to claim 10, wherein:
the tensile strained epitaxial layer and the compressive strained epitaxial layer are both made of SiGe;
the atomic percentage of Ge in the tensile strained epitaxial layer is less than the atomic percentage of Ge in the SiGe relaxed layer; and
the atomic percentage of Ge in the compressive strained epitaxial layer is larger than the atomic percentage of Ge in the SiGe relaxed layer.

14. The semiconductor device according to claim 10, wherein the tensile strained epitaxial layer is made of Si, and the compressive strained epitaxial layer is made of Ge.

15. The semiconductor device according to claim 10, wherein the material for forming the tensile strained epitaxial layer comprises Si:C.

16. The semiconductor device according to claim 10, wherein:
the SiGe relaxed layer further comprises an etching stop layer.

17. The semiconductor device according to claim 16, wherein:
the atomic percentage of Ge in the etching stop layer is different from that in the SiGe relaxed layer.

18. The semiconductor device according to claim 11, wherein the tensile strained epitaxial layer is made of a material having a lattice constant less than that of the SiGe relaxed layer in a relaxed state, and the compressive strained epitaxial layer is made of a material having a lattice constant larger than that of the SiGe relaxed layer in a relaxed state.

19. The semiconductor device according to claim 11, wherein:
the tensile strained epitaxial layer and the compressive strained epitaxial layer are both made of SiGe;
the atomic percentage of Ge in the tensile strained epitaxial layer is less than the atomic percentage of Ge in the SiGe relaxed layer; and
the atomic percentage of Ge in the compressive strained epitaxial layer is larger than the atomic percentage of Ge in the SiGe relaxed layer.

20. The semiconductor device according to claim 11, wherein the tensile strained epitaxial layer is made of Si, and the compressive strained epitaxial layer is made of Ge.
